(19) United States
(12) Patent Application Publication
(10) Pub. No.: US 2022/0149587 A1
(43) Pub. Date: May 12, 2022

(54) Visible Light Source

(71) Applicant: Nippon Telegraph and Telephone Corporation, Tokyo (JP)

(72) Inventors: Junji Sakamoto, Musashino-shi, Tokyo (JP); Toshikazu Hashimoto, Musashino-shi, Tokyo (JP)

(21) Appl. No.: 17/438,842

(22) PCT Filed: Apr. 16, 2019
(86) PCT No.: PCT/JP2019/016364

§ 371 Date: Sep. 13, 2021

(51) Int. Cl. H01S 5/0225; G02B 6/125; H01S 5/40; G02B 6/12

(52) U.S. Cl. CPC H01S 5/0225; G02B 6/12007; H01S 5/4087; G02B 6/125

(57) ABSTRACT

A visible light source capable of preventing degradation of a laser diode and accurately monitoring light of a plurality of wavelengths without hermetic sealing is provided. The visible light source includes a laser diode that is configured to output visible light, and a planar lightwave circuit (PLC) including an input waveguide optically coupled to the laser diode. A space is provided between an emission end face of the laser diode and the input waveguide, and is filled with an inorganic material.

### TECHNICAL FIELD

The present invention relates to a visible light source, and more particularly to an optical multiplexing circuit capable of multiplexing light of a plurality of wavelengths such as three primary colors of light and monitoring the intensity of light of each wavelength, and a visible light source including the optical multiplexing circuit.

### BACKGROUND ART

In recent years, a small light source including laser diodes (LDs) that output light of three primary colors of red light (R), green light (G), and blue light (B) as a light source to be applied to a glasses-type terminal and a small pico projector has been developed. Since LDs have a higher directionality than LEDs, a focus-free projector can be realized. Further, since LDs have a high light emission efficiency and a low power consumption, and also a high color reproducibility, LDs have recently been attracting attention.

FIG. 1 illustrates a typical light source of a projector using LDs. The light source for the projector includes LDs 1 to 3 that output light with a single wavelength of respective colors of R, G, and B, lenses 4 to 6 that collimate the light output from the LDs 1 to 3, and dichroic mirrors 10 to 12 that multiplex the respective light and output the light to a MEMS mirror 16. RGB light combined into a single beam is swept by using the MEMS mirror 16 or the like and is synchronized with modulation of the LDs, and thus a video is projected onto a screen 17. Half mirrors 7 to 9 are respectively inserted between the lenses 4 to 6 and the dichroic mirrors 10 to 12, and white balance is adjusted by monitoring the divided light of each color by using photodiodes (PDs) 13 to 15.

In general, an LD emits light in a longitudinal direction of a resonator; however, because the accuracy when monitoring the rear side is poor, it is common to monitor the front side from which light is emitted (front monitoring). As illustrated in FIG. 1, for use as an RGB light source, bulk optical components such as the LDs 1 to 3, the lenses 4 to 6, the half mirrors 7 to 9, and the dichroic mirrors 10 to 12 need to be combined with a spatial optical system. Furthermore, for monitoring for an adjustment of white balance, since bulk components such as the half mirrors 7 to 9 and the PDs 13 to 15 are needed and the optical system increases in size, there is a problem in that a reduction in the size of the light source is hindered.

On the other hand, an RGB coupler using a planar lightwave circuit (PLC) instead of a spatial optical system using bulk components has been attracting attention (for example, see Non Patent Literature 1). In a PLC, an optical waveguide is produced on a planar substrate such as Si by patterning by photolithography or the like, and reactive ion etching, and a plurality of basic optical circuits (for example, a directional coupler, a Mach-Zehnder interferometer, and the like) are combined, and thus various functions can be achieved (for example, see Non Patent Literatures 2 and 3).

FIG. 2 illustrates a basic structure of an RGB coupler using a PLC. An RGB coupler module including LDs 21 to 23 of respective colors of G, B, and R and a PLC-type RGB coupler 20 is illustrated. The RGB coupler 20 includes first to third waveguides 31 to 33 and first and second multiplexers 34 and 35 that multiplex light from two waveguides into a single waveguide. As methods of realizing a multiplexer in an RGB coupler module, there are a method of using symmetrical directional couplers having the same waveguide width, a method of using a Mach-Zehnder interferometer (for example, see Non Patent Literature 1), and a method of using a mode coupler (for example, see Non Patent Literature 4), and the like.

By using a PLC, a spatial optical system using a lens, a dichroic mirror, or the like can be integrated on one chip. Further, since the LD of R and the LD of G have a weaker output than the LD of B, an RRGGB light source in which two LDs of R and two LDs of G are prepared is used. As described in Non Patent Literature 2, by using mode multiplexing, light with the same wavelength can be multiplexed in different modes, and an RRGGB coupler can also be easily realized by using a PLC.

FIG. 3 illustrates a configuration of an RGB coupler using two directional couplers. An RGB coupler 100 using the PLC includes first to third input waveguides 101 to 103, first and second directional couplers 104 and 105, and an output waveguide 106 connected to the second input waveguide 102.

A waveguide length, a waveguide width, and a gap between the waveguides are designed such that the first directional coupler 104 couples light of λ2 incident from the first input waveguide 101 to the second input waveguide 102, and couples light of λ1 incident from the second input waveguide 102 to the first input waveguide 101 and back to the second input waveguide 102. A waveguide length, a waveguide width, and a gap between the waveguides are designed such that the second directional coupler 105 couples light of λ3 incident from the third input waveguide 103 to the second input waveguide 102, and passes light of λ1 and λ2 coupled to the second input waveguide 102 in the first directional coupler 104.

For example, green light G (wavelength λ2) is incident on the first input waveguide 101, blue light B (wavelength λ1) is incident on the second input waveguide 102, red light R (wavelength λ3) is incident on the third input waveguide 103, and the three colors of light R, G, and B are multiplexed by the first and second directional couplers 104 and 105 and output from the output waveguide 106. Light of 450 nm, light of 520 nm, and light of 638 nm are used as the wavelengths of λ1, λ2, and λ3, respectively.

Thus, it is necessary to configure a visible light source including a monitoring function for adjustment of white balance by applying such an RGB coupler.

### CITATION LIST

### Non Patent Literature

[Non Patent Literature 1] A. Nakao, R. Morimoto, Y. Kato, Y. Kakinoki, K. Ogawa and T. Katsuyama, “Integrated Waveguide-type Red-green-blue Beam Combiners for Compact Projection-type Displays”, Optics Communications 320 (2014) 45-48
[Non Patent Literature 2] Y. Hibino, “Arrayed-Waveguide-Grating Multi/Demultiplexers for Photonic Networks,” IEEE CIRCUITS & DEVICES, Nov., 2000, pp. 21-27
[Non Patent Literature 3] A. Himeno, et al., “Silica-Based Planar Lightwave Circuits,” J. Sel. Top. Q. E., vol. 4, 1998, pp. 913-924
[Non Patent Literature 4] J. Sakamoto et al. “High-efficiency Multiple-light-source red-green-blue Power Combiner with Optical Waveguide Mode Coupling Technique,” Proc. of SPIE Vol. 10126 101260 M-2

### SUMMARY OF THE INVENTION

An object of the present invention is to provide an optical multiplexing circuit capable of preventing degradation of a laser diode and accurately monitoring light of a plurality of wavelengths without hermetic sealing, and a visible light source including the optical multiplexing circuit.

According to the present invention, in order to achieve such an object, an embodiment of a visible light source includes a laser diode that is configured to output visible light, and a planar lightwave circuit (PLC) including an input waveguide optically coupled to the laser diode, where a space is provided between an emission end face of the laser diode and the input waveguide, and is filled with an inorganic material.

According to the present invention, it is possible to prevent degradation of a laser diode and achieve a long life, and also accurately monitor light of a plurality of wavelengths without hermetic sealing.

### BRIEF DESCRIPTION OF DRAWINGS

FIG. 1 is a diagram illustrating a typical light source of a projector using an LD.

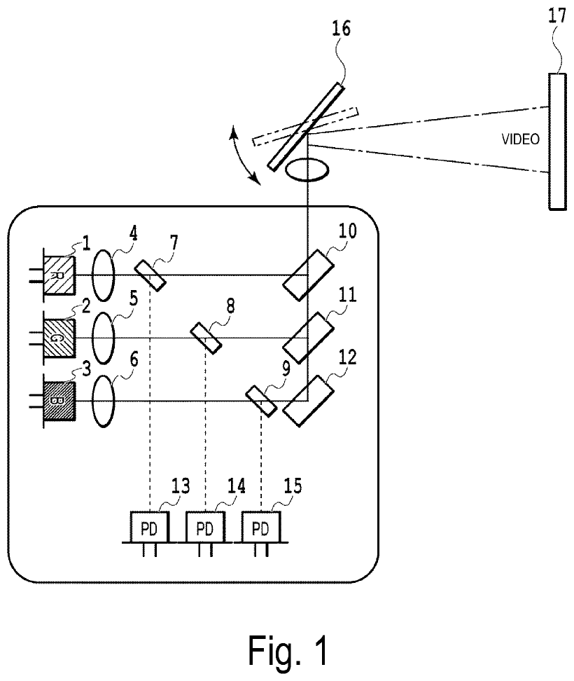

FIG. 2 is a diagram illustrating a basic structure of an RGB coupler using a PLC.

FIG. 3 is a diagram illustrating a configuration of an RGB coupler using two directional couplers.

FIG. 4 is a diagram illustrating a light source with a monitoring function according to a first embodiment of the present invention.

FIG. 5 is a diagram illustrating a state of coupling of an LD and an RGB coupler of a light source with a monitoring function according to a second embodiment of the present invention.

FIG. 6 is a diagram illustrating another example of the coupling of the LD and the RGB coupler according to the second embodiment.

### DESCRIPTION OF EMBODIMENTS

Hereinafter, embodiments of the present disclosure will be described in detail with reference to the drawings. In the present embodiment, description is given for the case of a method using a directional coupler as a multiplexer, but the present invention is not limited to a multiplexing method.

### First Embodiment

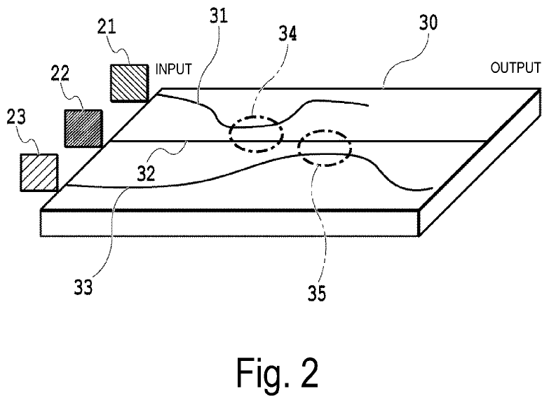

In the optical connection between the LDs 21 to 23 and the RGB coupler 20 illustrated in FIG. 2, optical axes are generally aligned with each other through a space. However, the LDs 21 to 23 for visible light used in the light source have a wavelength shorter and also have a mode field diameter smaller than those of an LD in a communication wavelength band. Therefore, even when the LDs 21 to 23 have the same light output power as that of the communication wavelength band, a power density thereof is higher by one order of magnitude. Furthermore, since the energy of the ultraviolet light from the visible light is higher than the energy of the light in the communication wavelength band, an emission end face is severely degraded due to a dust collection effect of the light, and the life of the LD is shortened. Thus, deterioration is suppressed by hermetically sealing the LD and the RGB coupler in a housing made of a metal or a resin.

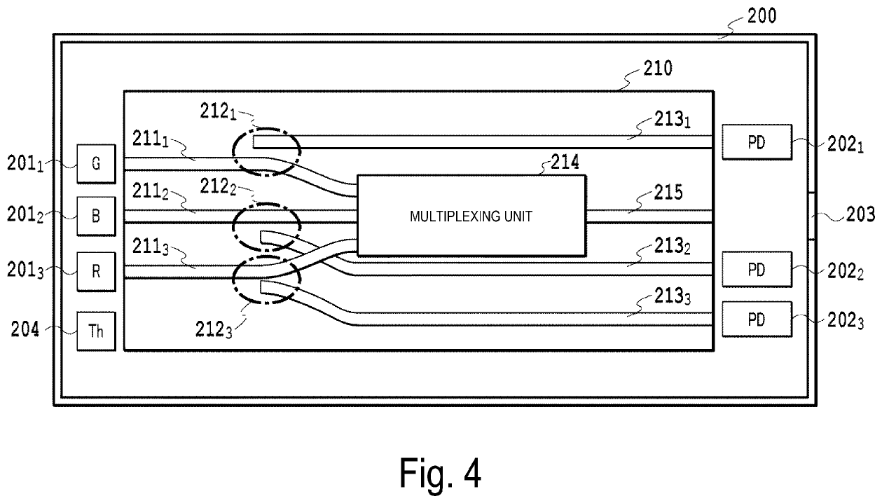

FIG. 4 illustrates a light source with a monitoring function according to a first embodiment of the present invention. A light source 200 with a monitoring function includes first to third LDs 201₁ to 201₃ that respectively output light of respective colors of G, B, and R, a PLC-type RGB coupler 210, and first to third PDs 202₁ to 202₃ optically connected to the RGB coupler 210. An output of the RGB coupler 210 is taken out of a window 203 provided in a housing, and, for example, when the output is applied to a projector, a MEMS mirror is irradiated with the output.

Furthermore, the light source 200 with a monitoring function includes a thermistor 204. Since an oscillation wavelength of each of the LDs 201 fluctuates due to a change in temperature, feedback control is performed on the LDs 201 in accordance with the change in temperature.

The PLC-type RGB coupler 210 includes first to third input waveguides 211₁ to 211₃ optically connected to the first to third LDs 201₁ to 201₃, first to third branching units 212₁ to 212₃ that divide light propagating through the waveguide into two, a multiplexing unit 214 that multiplexes one beam of the light divided by each of the first to third branching units 212₁ to 212₃, first to third monitoring waveguides 213₁ to 213₃ that output the other beam of the light divided by each of the first to third branching units 212₁ to 212₃ to the first to third PDs 202₁ to 202₃, and an output waveguide 215 that outputs the light multiplexed by the multiplexing unit 214.

In the PLC-type RGB coupler 210, light incident on each of the first to third input waveguides 211₁ to 211₃ is divided into two by each of the first to third branching units 212₁ to 212₃. One beam of the divided light is output to the first to third PDs 202₁ to 202₃ via the first to third monitoring waveguides 213₁ to 213₃, and the other beam of the divided light is multiplexed by the multiplexing unit 214 and output to the output waveguide 215.

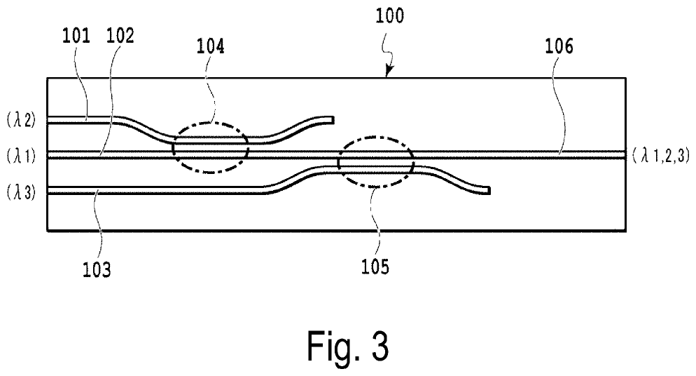

An optical multiplexing circuit using the directional coupler illustrated in FIG. 3 can be used as the multiplexing unit 214. In this case, the first to third input waveguides 211₁ to 211₃ are coupled to the first to third input waveguides 101 to 103 illustrated in FIG. 3, respectively, and the output waveguide 215 is coupled to the output waveguide 106 illustrated in FIG. 3. However, the multiplexing unit 214 is not limited thereto, and another multiplexing unit of a waveguide type (for example, a Mach-Zehnder interferometer, a mode coupler, or the like) may be used.

As illustrated in FIG. 4, when light propagating through the first to third input waveguides 211₁ to 211₃ is divided by the first to third branching units 212₁ to 212₃, respectively, a coupling characteristic between the first to third LDs 201₁ to 201₃ and the first to third input waveguides 211₁ to 211₃ can be monitored. In addition, it is possible to adjust white balance as a light source by using a monitoring value of the first to third PDs 202₁ to 202₃ by recognizing a multiplexing characteristic of the multiplexing unit 214 in advance.

### Second Embodiment

On the other hand, hermetic sealing by a housing made of a metal or a resin increases a production process of a visible light source and increases a manufacturing cost. Thus, an optical connection between the LD and the RGB coupler 20 that does not require hermetic sealing is achieved. A configuration of a light source with a monitoring function according to a second embodiment is the same as that according to the first embodiment, and the method of optically coupling the first to third LDs 201₁ to 201₃ and the RGB coupler 210 is different.

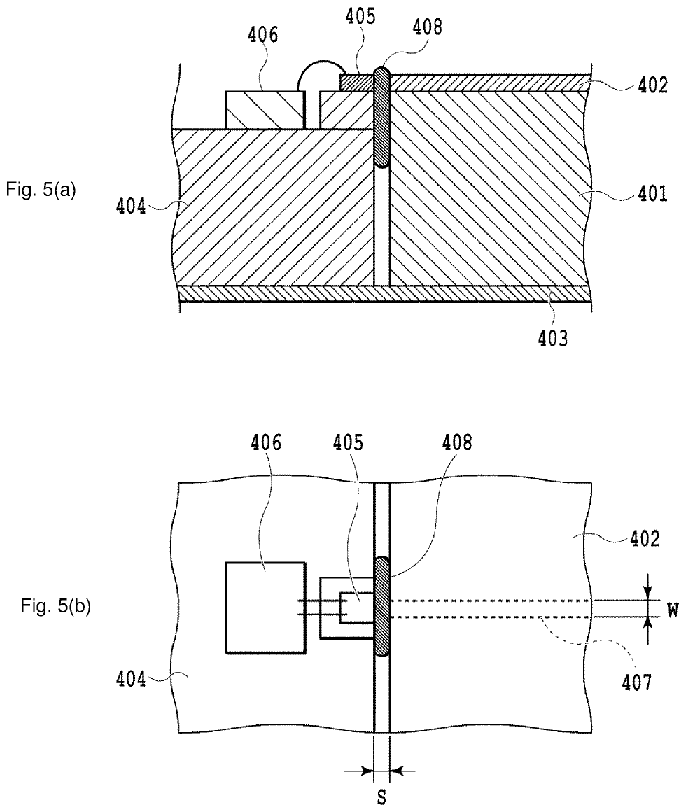

FIG. 5 illustrates a state of coupling of an LD and an RGB coupler of the light source with the monitoring function according to the second embodiment of the present invention. As illustrated in FIG. 5(a), the RGB coupler is acquired by forming an optical circuit in a SiO₂ layer 402 formed on a Si substrate 401, and being fixed to a bottom portion of a housing 403 made of a metal. An LD 405 of each color of R, G, and B together with a chip 406 including a drive circuit are mounted on a mounting 404 for heat radiation, and are fixed to a bottom portion of the housing 403.

As described above, optical connection between the LD 405 and an input waveguide 407 formed in the SiO₂ layer 402 is performed through a space. As illustrated in FIG. 5(b), a width W of the waveguide 407 is approximately several μm, and a width S of the space is also approximately several μm. The size of the chip of the LD 405 is approximately 150 μm square, but an active layer has a width of approximately several μm, and is aligned so as to face the input waveguide 407. In the second embodiment, an inorganic material 408 such as polysilazane fills the space and is sintered.

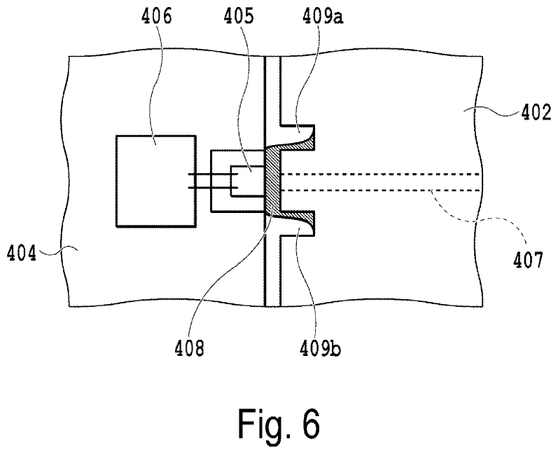

FIG. 6 illustrates another example of the coupling of the LD and the RGB coupler according to the second embodiment. The inorganic material 408 may cover a space between an emission end of the LD 405 and the input waveguide 407. Thus, grooves 409a and 409b are formed on both sides of the input waveguide 407 formed in the RGB coupler such that the inorganic material 408 does not spread out along the space.

With such a configuration, an emission end of the LD of each color of R, G, and B is covered by an inorganic material, and thus it is possible to prevent an organic substance from adhering to an emission end face due to a dust collection effect of light or the like. As a result, degradation of the LD can be prevented and a long life can be achieved, and white balance as a light source can also be accurately adjusted without hermetic sealing.

### Third Embodiment

An emission end of the first to third monitoring waveguides 213₁ to 213₃ of the RGB coupler 210 illustrated in FIG. 4 may emit light having a power lower than that of the output of the first to third LDs 201₁ to 201₃, but the light has a short wavelength, and thus degradation of the emission end face may occur due to light with a short wavelength. Further, an emission end of the output waveguide 215 emits light that is in a broad wavelength range in which light of each color of R, G, and B is multiplexed, but has a high power, and degradation of an emission end face may still occur. Thus, it is preferable that the mode field diameter be increased by providing a spot size convertor (SSC) at the emission end of the first to third monitoring waveguides 213₁ to 213₃ and the output waveguide 215 to reduce a power density at the emission end face.

1. A visible light source, comprising:
a laser diode that is configured to output visible light; and
a planar lightwave circuit (PLC) including an input waveguide optically coupled to the laser diode,
wherein a space is provided between an emission end face of the laser diode and the input waveguide, and is filled with an inorganic material.

2. A visible light source, comprising:
a plurality of laser diodes that are configured to output visible light;
a plurality of input waveguides each optically coupled to a corresponding one of the plurality of laser diodes;
a multiplexing unit that is configured to multiplex light from the plurality of input waveguides; and
an output waveguide that is configured to output light multiplexed by the multiplexing unit,
wherein a space is provided between an emission end face of the plurality of laser diodes and the plurality of input waveguides, and is filled with an inorganic material.

3. The visible light source according to claim 2, further comprising:
a plurality of branching units that are each inserted into a corresponding one of the plurality of input waveguides, and each configured to divide light from a corresponding one of the plurality of input waveguides, output one beam of the divided light to the multiplexing unit, and output another beam of the divided light to a monitoring waveguide; and
a plurality of photodiodes each optically coupled to a corresponding one of the plurality of monitoring waveguides.

4. The visible light source according to claim 2, further comprising a spot size converter at an emission end face of the output waveguide.

5. The visible light source according to claim 2, wherein the plurality of laser diodes are three laser diodes that are configured to output three primary colors of red light (R), green light (G), and blue light (B).

6. The visible light source according to claim 3, further comprising a spot size converter at an emission end face of the output waveguide.

7. The visible light source according to claim 3, wherein the plurality of laser diodes are three laser diodes that are configured to output three primary colors of red light (R), green light (G), and blue light (B).

8. The visible light source according to claim 4, wherein the plurality of laser diodes are three laser diodes that are configured to output three primary colors of red light (R), green light (G), and blue light (B).
